(19) United States
(12) Patent Application Publication
(10) Pub. No.: US 2026/0011679 A1
(43) Pub. Date: Jan. 8, 2026

(54) HIGH DIE STACK PACKAGE WITH VERTICAL DIE-TO-DIE INTERCONNECTS

(71) Applicant: Micron Technology, Inc., Boise, ID (US)

(72) Inventors: Kelvin Tan Aik Boo, Singapore (SG); Seng Kim Ye, Singapore (SG); Hong Wan Ng, Singapore (SG); Chin Hui Chong, Singapore (SG)

(21) Appl. No.: 19/260,160

(22) Filed: Jul. 3, 2025

Related U.S. Application Data
(60) Provisional application No. 63/668,765, filed on Jul. 8, 2024.

(51) Int. Cl. H01L 23/00; H01L 23/16; H01L 23/31; H01L 25/18; H10B 80/00

(52) U.S. Cl. CPC H01L 24/49; H01L 23/16; H01L 24/48; H01L 24/85; H01L 25/18; H01L 23/3128; H01L 2224/48108; H01L 2224/48147; H01L 2224/48247; H01L 2224/49109; H01L 2224/49112; H01L 2224/85203; H01L 2224/85897; H01L 2224/85898; H01L 2225/06506; H01L 2225/0651; H01L 2225/06562; H10B 80/00

(57) ABSTRACT

Systems, devices, and methods for high die stack packages with vertical die-to-die interconnects are provided herein. A die stack package can include a substrate, a lower die stack carried by the substrate, a spacer carried by the substrate, an upper die stack carried by the spacer, a plurality of wire bonds, and a plurality of vertical wires. The lower die stack can include a plurality of lower dies stacked in a cascading arrangement. The upper die stack can include a plurality of upper dies stacked in a cascading arrangement in a same direction as the plurality of lower dies. The wire bonds can electrically couple adjacent ones of the lower dies. An nth vertical wire can extend vertically between and electrically couple an nth upper die and an nth lower die. In some embodiments, the die stack package further includes an input-and-output extender carried by the substrate.

### CROSS-REFERENCE TO RELATED APPLICATION(S)

The present application claims priority to U.S. Provisional Patent Application No. 63/668,765, filed Jul. 8, 2024, the disclosure of which is incorporated herein by reference in its entirety.

### TECHNICAL FIELD

The present disclosure generally relates to semiconductor device assemblies, and more particularly relates to high die stack packages with vertical die-to-die interconnects.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIG. 1A is a partially schematic cross-sectional diagram of a die stack package including two die stacks.

FIG. 1B is a partially schematic cross-sectional diagram of a die stack package including four die stacks.

FIG. 2 is a partially schematic cross-sectional diagram of a die stack package configured in accordance with embodiments of the present technology.

FIG. 3 is a partially schematic cross-sectional diagram of another die stack package configured in accordance with embodiments of the present technology.

FIG. 4 is a flowchart illustrating a method for manufacturing a die stack package in accordance with embodiments of the present technology.

A person skilled in the relevant art will understand that the features shown in the drawings are for purposes of illustrations, and variations, including different and/or additional features and arrangements thereof, are possible.

### DETAILED DESCRIPTION

The demand for more dies in semiconductor packages is driven by the increasing need for higher performance, greater functionality, and improved energy efficiency in modern electronic devices. As applications in fields like artificial intelligence, high-performance computing, and mobile technology evolve, the necessity for integrating more computational power, more memory and/or storage, and specialized functions within a single package has grown significantly. However, as more dies are integrated into a single package, the physical space occupied by semiconductor packages and the necessary interconnections between dies become more problematic. This can lead to challenges in maintaining signal integrity, managing thermal dissipation, and ensuring reliable power delivery. Additionally, as the package becomes denser, the complexity of routing signals between the dies and the external connections increases.

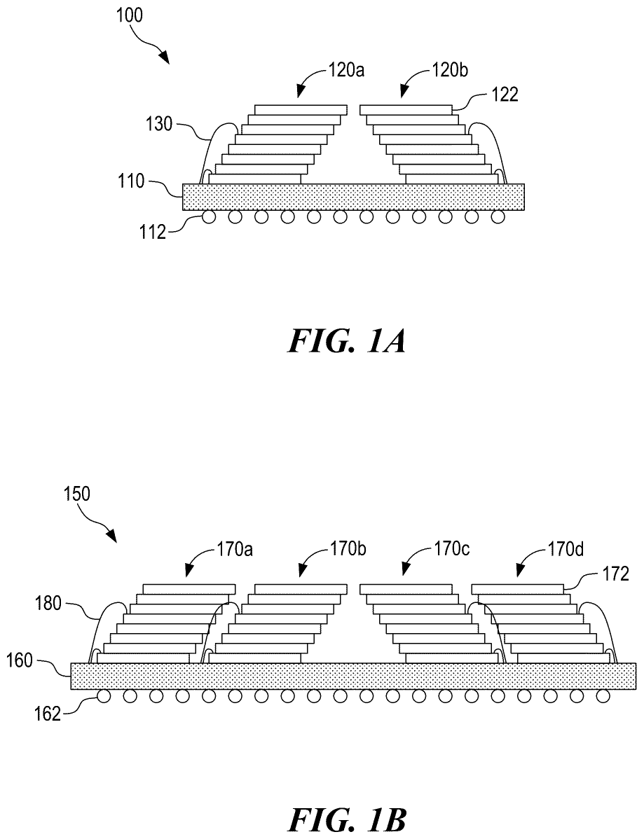

FIG. 1A is a partially schematic cross-sectional diagram of a die stack package 100. The die stack package 100 includes a substrate 110, a first die stack 120a, and a second die stack 120b. The substrate 110 can be coupled to other components not shown (e.g., a package substrate) via interconnections 112 (e.g., solder balls) such that the die stack package 100 can form part of a system-in-package (SiP). Each of the first die stack 120a and the second die stack 120b is carried by the substrate 110 such that the first die stack 120a and the second die stack 120b are arranged side-by-side. The first die stack 120a and the second die stack 120b can each include a plurality of dies 122 (in the illustrated embodiment, each die stack includes eight dies) stacked on top of one another in a cascading arrangement (e.g., forming steps), as illustrated. Also, one or more of the dies 122 in each of the first die stack 120a and the second die stack 120b can be electrically coupled to the substrate 110 via corresponding wire bonds 130. In particular, the wire bonds 130 can be coupled to portions of the upper surfaces of the one or more dies 122 that are exposed by virtue of the cascading arrangement.

FIG. 1B is a partially schematic cross-sectional diagram of a die stack package 150. The die stack package 150 includes a substrate 160, a first die stack 170a, a second die stack 170b, a third die stack 170c, and a fourth die stack 170d. The substrate 160 can be coupled to other components not shown (e.g., a package substrate) via interconnections 162 (e.g., solder balls) such that the die stack package 150 can form part of a system-in-package (SiP). Each of the first through fourth die stacks 170a-d is carried by the substrate 160 such that the first through fourth die stacks 170a-d are arranged side-by-side. The first through fourth die stacks 170a-d can each include a plurality of dies 172 (in the illustrated embodiment, each die stack includes eight dies) stacked on top of one another in a cascading arrangement (e.g., forming steps), as illustrated. Also, one or more of the dies 172 in each of the first through fourth die stacks 170a-d can be electrically coupled to the substrate 160 via corresponding wire bonds 180. In particular, the wire bonds 180 can be coupled to portions of the upper surfaces of the one or more dies 172 that are exposed by virtue of the cascading arrangement.

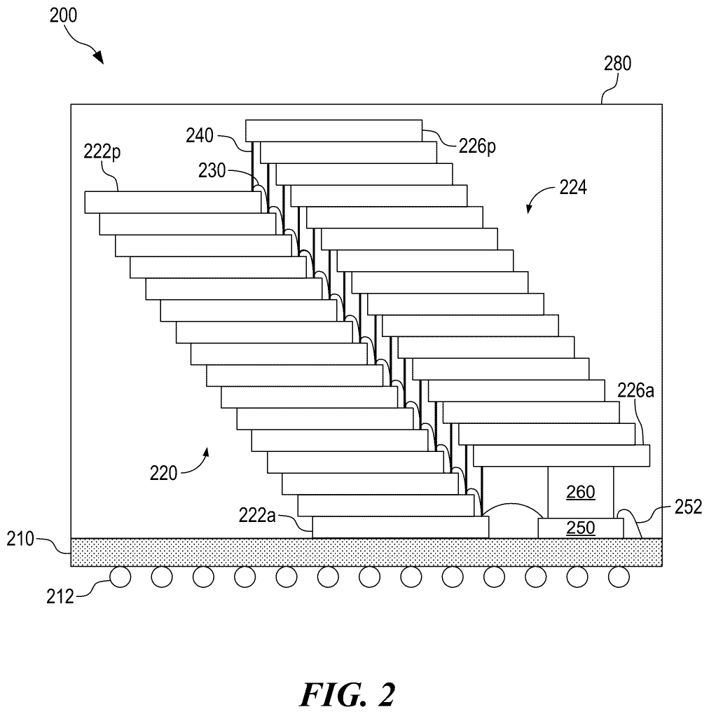

Comparing the die stack package 150 (FIG. 1B) to the die stack package 100 (FIG. 1A), the substrate 160 has a greater lateral dimension (e.g., length, width) than the substrate 110 in order to accommodate double the number of die stacks carried thereon. However, SiPs may not be able to accommodate die stack packages with increased x-y form factors given space constraints. Additionally or alternatively, die stack packages with large lateral dimensions may impose undue constraints on other components of the SiP. Moreover, if a die stack package were to include a greater number of die stacks (e.g., eight, sixteen, etc.), continuously expanding the lateral dimension of the substrate thereof can be impractical. Merely stacking the first die stack 170a on the second die stack 170b and stacking the fourth die stack 170d on the third die stack 170c to continue the cascading arrangement upward would also be impossible. While this can seemingly keep the lateral dimension of the substrate 160 equal to that of the substrate 110, because the first and fourth die stacks 170a cascade upward and toward one another, the first and fourth die stacks 170a would need to occupy the same space. To address these problems and others, embodiments of the present technology provide high die stack packages with vertical die-to-die interconnects, as illustrated in and discussed below with reference to FIGS. 2-4.

FIG. 2 is a partially schematic cross-sectional diagram of a die stack package 200 configured in accordance with embodiments of the present technology. The die stack package 200 includes a substrate 210 (also referred to herein as “the interposer”), a first or lower die stack 220, a second or upper die stack 224, an input-and-output extender (“IOE”) 250, a spacer 260, and an encapsulant 280.

The substrate 210 can be coupled to other components not shown (e.g., a package substrate) via interconnections 212 (e.g., solder balls) such that the die stack package 200 can form part of a system-in-package (SiP). The lower die stack 220 can include a plurality of first or lower dies, individually labeled 222a-p and collectively referred to as “the lower dies 222,” that are stacked on top of one another, as shown. In FIG. 2, the lower die stack 220 includes 16 lower dies 222. The IOE 250 (also referred to as the multiplexer) can also by carried by the substrate and electrically coupled thereto by IOE wire bonds 252. The spacer 260 can be carried by the IOE 250. The spacer 260 can comprise a dielectric or other insulating material. The upper die stack 224 can include a plurality of second or upper dies, individually labeled 226a-p and collectively referred to as “the upper dies 226,” that are stacked on top of one another, as shown. In FIG. 2, the upper die stack 224 includes 16 upper dies 226. The lower dies 222 and the upper dies 226 can include volatile memory dies (e.g., DRAM dies, LPDRAM dies), non-volatile memory dies (e.g., NAND dies, NOR dies, PCM dies, FeRAM dies, MRAM dies), Application-Specific Integrated Circuit (ASIC) dies, IOE dies, controller dies, and/or any other suitable dies.

In the illustrated embodiment, the plurality of lower dies 222 are stacked on top of one another in a cascading arrangement (e.g., forming steps), and the plurality of upper dies 226 are similarly stacked on top of one another in a cascading arrangement (e.g., forming steps). In particular, the lower dies 222 and the upper dies 226 are stacked to cascade in the same direction (e.g., upward and leftward, away from the IOE 250 in FIG. 2). Also, a first lower die 222a is carried by the substrate 210 and a first upper die 226a is carried by the spacer 260. Therefore, the spacer 260 (and the IOE 250) lifts the upper die stack 224 such that the nth upper die 226n is spaced apart and at least partially above the nth lower die 222n. For example, the first upper die 226a is spaced apart and positioned at least partially above the first lower die 222a, and the 16^{th} upper die 226p is spaced apart and positioned at least partially above the 16^{th} lower die 222p.

Adjacent ones of the lower dies 222 can be electrically coupled to one another via wire bonds 230. The first lower die 222 is also electrically coupled to the IOE 250 via one or more of the wire bonds 230. Therefore, all of the lower dies 222 can be electrically coupled to the substrate 210 via one another, the wire bonds 230, the IOE 250, and the IOE wire bond 252. Moreover, the n^{th} upper die 226n can be electrically coupled to the nth lower die 222n via vertical die-to-die interconnects or vertical wires 240. As shown, each vertical wire 240 is coupled to a portion of the upper surface of a corresponding lower die 222 that is exposed by virtue of the cascading arrangement, extends vertically upward, and is coupled to a portion of the lower surface of a corresponding upper die 226 that is exposed by virtue of the cascading arrangement. Therefore, although none of the upper dies 226 are directly electrically coupled to the substrate 210, all of the upper dies 226 are electrically coupled to the substrate 210 via the vertical wires 240, the wire bonds 230, the IOE 250, and the IOE wire bond 252. In some embodiments, the lower dies 222 and the upper dies 226 are arranged in a face-to-face die stacking arrangement such that the upper dies 226 are “flipped upside down” and the vertical wires 240 extend between active faces of the lower dies 222 and the upper dies 226. In some embodiments, the vertical wires 240 are electrically coupled to the lower dies 222 and the upper dies 226 via pressure and thermal wire bonding, copper-to-copper wire bonding, hybrid bonding, and/or other suitable methods.

In some embodiments, at least one of the upper dies 226 (e.g., the first upper dic 226a) is directly electrically coupled to the substrate 210 and/or the IOE 250, such as via a vertical wire that may extend therebetween. In some embodiments, adjacent ones of the upper dies 226 can be electrically coupled to one another via wire bonds (e.g., similar to the wire bonds 230). In some embodiments, the die stack package 200 further includes film over wire (FOW) to encapsulate the wire bonds 230, 252. Also, one of ordinary skill in the art will appreciate that each of the lower die stack 220 and/or the upper die stack 224 can include a different number of dies (e.g., 4 dies, 8 dies, 32 dies, 64 dies, etc.).

By including the lower die stack 220 and the upper die stack 224, and electrically coupling the lower dies 222 and the upper dies 226 via the wire bonds 230 and the vertical wires 240, the die stack package 200 can easily stack any number of dies. Furthermore, because the dies are stacked on top of one another in either the lower die stack 220 or the upper die stack 22, the lateral dimension of the substrate 210, which defines the lateral dimension of the die stack package 200, can be smaller than, for example, the lateral dimension of the substrate 160 (FIG. 1B) while the die stack package 200 includes the same number of dies (e.g., 32 dies, as shown).

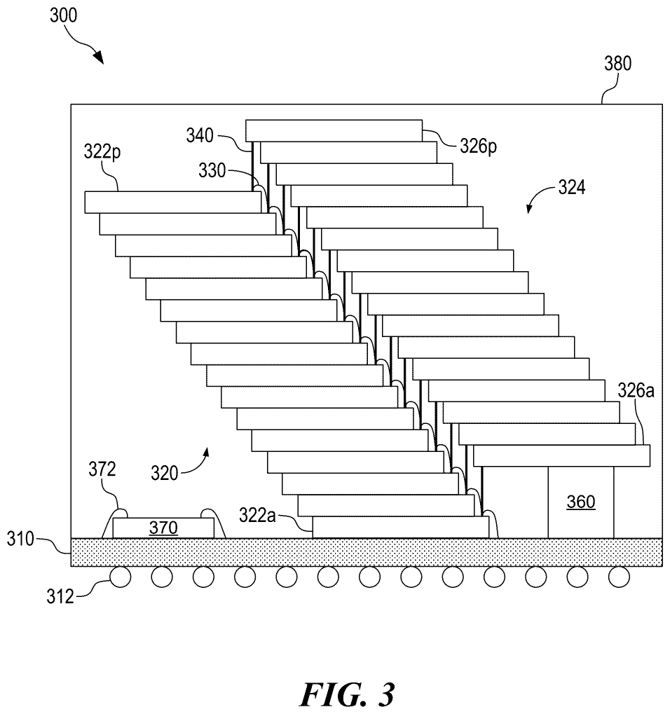

FIG. 3 is a partially schematic cross-sectional diagram of a die stack package 300 configured in accordance with embodiments of the present technology. The die stack package 300 can be generally similar to the die stack package 200 of FIG. 2. For example, the die stack package 300 includes a substrate 310 (also referred to herein as “the interposer”), a lower die stack 320, an upper die stack 324, a spacer 360, one or more semiconductor structures 370, and an encapsulant 380.

Like in the die stack package 200 of FIG. 2, the substrate 310 can be coupled to other components not shown (e.g., a package substrate) via interconnections 312 (e.g., solder balls) such that the die stack package 300 can form part of a system-in-package (SiP). The lower die stack 320 can include a plurality of lower dies, individually labeled 322a-p and collectively referred to as “the lower dies 322,” that are stacked on top of one another, as shown. In FIG. 3, the lower die stack 320 includes 16 lower dies 322. The upper die stack 324 can include a plurality of upper dies, individually labeled 326a-p and collectively referred to as “the upper dies 326,” that are stacked on top of one another, as shown. In FIG. 3, the upper die stack 324 includes 16 upper dies 326. The lower dies 322 and the upper dies 326 can include volatile memory dies (e.g., DRAM dies, LPDRAM dies), non-volatile memory dies (e.g., NAND dies, NOR dies, PCM dies, FeRAM dies, MRAM dies), ASIC dies, IOE dies, controller dies, and/or any other suitable dies.

Also, adjacent ones of the lower dies 322 can be electrically coupled to one another via wire bonds 330. Moreover, the nth upper die 326n can be electrically coupled to the n^{th} lower die 322n via vertical die-to-die interconnects or vertical wires 340. As shown, each vertical wire 340 is coupled to a portion of the upper surface of a corresponding lower die 322 that is exposed by virtue of the cascading arrangement, extends vertically upward, and is coupled to a portion of the lower surface of a corresponding upper die 326 that is exposed by virtue of the cascading arrangement.

Unlike the die stack package 200 of FIG. 2, however, the die stack package 300 does not include an IOE (e.g., the IOE 250). Thus, the spacer 360 is immediately carried by the substrate 310 and a first lower die 322a is directly electrically coupled to the substrate 310 (e.g., to a bond pad thereof) via the wire bonds 330 (or via flip chip). Additionally, FIG. 3 shows the semiconductor structure 370 carried by the substrate 310, positioned apart from the lower die stack 320 and the upper die stack 324, and electrically coupled to the substate 310 (e.g., to bond pads thereof) via semiconductor structure bond wires 372 (or via flip chip). The semiconductor structure 370 can include an ASIC, a capacitor, an inductor, and/or the like. In some embodiments, the semiconductor structure 370 can be positioned elsewhere in the die stack package 300, such as stacked between the substrate 310 and the spacer 360.

Referring to FIGS. 2 and 3 together, embodiments of the present technology provide a scalable die stack package that can include more than 32 dies. For example, as aforementioned, a die stack package can include a lower die stack and an upper die stack each including 32 dies stacked in a cascading arrangement. Thus, one of ordinary skill in the art will appreciate that die stack packages configured in accordance with embodiments of the present technology can include a wide range of number of dies while maintaining an x-y form factor smaller than that of conventional packages including the same number of dies and die stacks (e.g., the die stack package 150 of FIG. 1B).

Die stack packages configured in accordance with embodiments of the present technology also provide high manufacturability, electrical reliability, and thermal management. First, the die stack packages illustrated and described herein can be manufactured with commonly available and/or easily modifiable components, such as wires and interposers. Second, the electrical signals are communicated to and from the dies directly through the substrate and/or through the IOE, thereby maintaining the integrity of the signals. Third, the uppermost die of the upper die stack (e.g., the upper die 226p, 326p) can be exposed (e.g., not fully covered) or covered with a relatively thin layer of the encapsulant, thereby allowing the die stacks to cool off more quickly and efficiently than die stack packages with a relatively thick layer of the encapsulant.

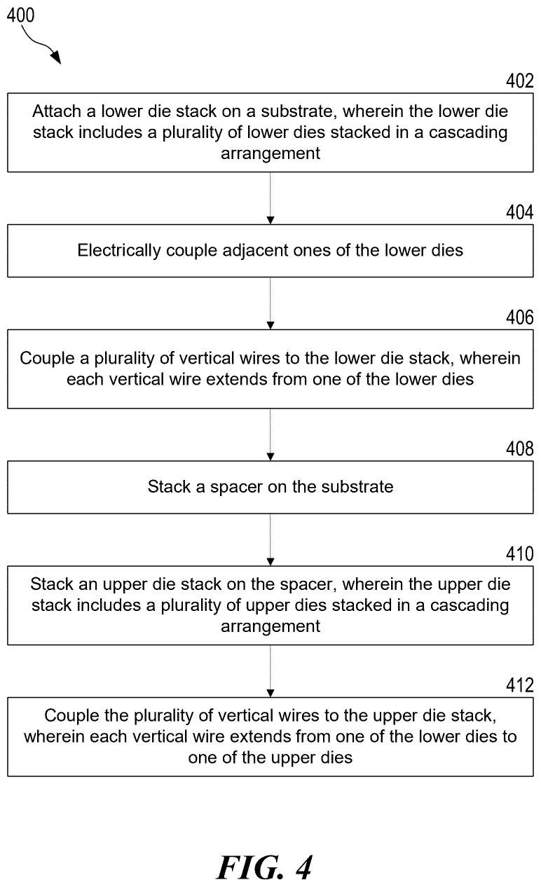

FIG. 4 is a flowchart illustrating a method 400 for manufacturing a die stack package in accordance with some embodiments of the present technology. While the steps of the method 400 are described below in a particular order, one or more of the steps can be performed in a different order or omitted, and the method 400 can include additional and/or alternative steps. Additionally, although the method 400 may be described below with reference to the embodiments of the present technology described herein, the method 400 can be performed with other embodiments of the present technology.

The method 400 begins at block 402 by attaching a lower die stack (e.g., the lower die stack 220) on a substrate (e.g., the substrate 210), wherein the lower die stack includes a plurality of lower dies (e.g., the lower dies 222) stacked in a cascading arrangement.

At block 404, the method 400 continues by electrically coupling adjacent ones of the lower dies. In some embodiments, the adjacent ones of the lower dies are electrically coupled via wire bonds (e.g., the wire bonds 230).

At block 406, the method 400 continues by coupling a plurality of vertical wires (e.g., the vertical wires 240) to the lower die stack, wherein each vertical wire extends from one of the lower dies. In some embodiments, each of the vertical wires are coupled to a corresponding one of the lower dies. The vertical wires can be coupled to the lower dies via pressure and thermal wire bonding, copper-to-copper wire bonding, hybrid bonding, and/or other suitable methods.

At block 408, the method 400 continues by stacking a spacer (e.g., the spacer 260) on the substrate. The spacer can comprise a dielectric or other insulating material.

At block 410, the method 400 continues by stacking an upper die stack (e.g., the upper die stack 224) on the spacer, wherein the upper die stack includes a plurality of upper dies (e.g., the upper dies 226) stacked in a cascading arrangement. In some embodiments, the upper dies and the lower dies are stacked in a cascading arrangement in the same direction. For example, the upper dies and the lower dies can cascade upward and away from the spacer.

At block 412, the method 400 continues by coupling the plurality of vertical wires to the upper die stack, wherein each vertical wire extends from one of the lower dies to one of the upper dies. The vertical wires can be coupled to the upper dies via pressure and thermal wire bonding, copper-to-copper wire bonding, hybrid bonding, and/or other suitable methods.

In some embodiments, the method 400 further comprises stacking an input-and-output extender (e.g., the IOE 250) on the substrate, wherein stacking the spacer on the substrate comprises stacking the spacer on the IOE, and electrically coupling the IOE to the substrate (e.g., via the IOE wire bonds 252) and to one of the lower dies (e.g., via the wire bonds 230).

In some embodiments, the method 400 further comprises stacking a semiconductor structure (e.g., the semiconductor structure 370) on the substrate, and electrically coupling the semiconductor structure to the substrate. The semiconductor structure can include an Application-Specific Integrated Circuit (ASIC), a capacitor, an inductor, and/or the like.

In some embodiments, the method 400 further comprises forming an encapsulant (e.g., the encapsulant 280) around the lower die stack and the upper die stack. The encapsulant can be formed such that a portion of an uppermost upper die (e.g., the upper die 226p) of the upper die stack is not covered by the encapsulant. This can facilitate thermal management of the die stack package.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

I/We claim:

1. A die stack package, comprising:
a substrate;
a lower die stack carried by the substrate, wherein the lower die stack includes a plurality of lower dies stacked in a cascading arrangement;
a spacer carried by the substrate;
an upper die stack carried by the spacer, wherein the upper die stack includes a plurality of upper dies stacked in a cascading arrangement in a same direction as the plurality of lower dies such that an n^{th} upper die is spaced apart and positioned at least partially above an n^{th} lower die;
a plurality of wire bonds electrically coupling adjacent ones of the lower dies; and
a plurality of vertical wires, wherein an n^{th} vertical wire extends vertically between and electrically couples the n^{th} upper die and the n^{th} lower die.

2. The die stack package of claim 1, further comprising an input-and-output extender (IOE) carried by the substrate, wherein a first one of the lower dies immediately carried by the substrate is electrically coupled to the IOE via one or more wire bonds, wherein the IOE is electrically coupled to the substrate via one or more IOE wire bonds, and wherein the spacer is carried by the IOE.

3. The die stack package of claim 1, wherein the spacer is immediately carried by the substrate, and wherein a first one of the lower dies immediately carried by the substrate is electrically coupled to the substrate.

4. The die stack package of claim 1, further comprising a semiconductor structure carried by the substrate and spaced apart from the spacer, wherein the semiconductor structure includes an Application-Specific Integrated Circuit (ASIC), a capacitor, or an inductor.

5. The die stack package of claim 1, further comprising a semiconductor structure carried by the substrate and positioned underneath the spacer, wherein the semiconductor structure includes an Application-Specific Integrated Circuit (ASIC), a capacitor, or an inductor.

6. The die stack package of claim 1, wherein the plurality of lower dies includes 16 lower dies, and wherein the plurality of upper dies includes 16 upper dies.

7. The die stack package of claim 1, wherein the plurality of lower dies includes 32 lower dies, and wherein the plurality of upper dies includes 32 upper dies.

8. The die stack package of claim 1, further comprising an encapsulant around the lower die stack and the upper die stack, wherein an uppermost upper die is not fully covered by the encapsulant.

9. The die stack package of claim 1, wherein the plurality of lower dies and the plurality of upper dies are oriented in a face-to-face die stack arrangement such that the vertical wires extend between active faces of the lower dies and the upper dies.

10. The die stack package of claim 1, wherein each of the plurality of lower dies and the plurality of upper dies comprises a volatile memory die.

11. The die stack package of claim 1, wherein each of the plurality of lower dies and the plurality of upper dies comprises a non-volatile memory die.

12. The die stack package of claim 1, wherein the plurality of lower dies and the plurality of upper dies are stacked in the cascading arrangement extending upward and away from the spacer.

13. The die stack package of claim 1, wherein the plurality of vertical wires are electrically coupled to the plurality of lower dies and the plurality of upper dies via pressure and thermal wire bonding.

14. The die stack package of claim 1, wherein the plurality of vertical wires are electrically coupled to the plurality of lower dies and the plurality of upper dies via copper-to-copper wire bonding.

15. A die stack package, comprising:
an interposer;
a spacer carried by the interposer;
a first die stack carried by the interposer, wherein the first die stack includes a plurality of first dies stacked in a cascading arrangement extending upward and away from the spacer;
a plurality of wire bonds electrically coupling adjacent ones of the first dies;
a second die stack carried by the spacer, wherein the second die stack includes a plurality of second dies stacked in a cascading arrangement extending upward and away from the spacer; and
a plurality of vertical die-to-die interconnects, wherein each vertical die-to-die interconnect extends between one of the first dies and a corresponding one of the second dies.

16. The die stack package of claim 15, further comprising an input-and-output extender (IOE) carried by the interposer, wherein the spacer is carried by the IOE, wherein the IOE is electrically coupled to the interposer via IOE wire bonds, and wherein the IOE is electrically coupled to one of the first dies.

17. A method for manufacturing a die stack package, the method comprising:
attaching a lower die stack on a substrate, wherein the lower die stack includes a plurality of lower dies stacked in a cascading arrangement;
electrically coupling adjacent ones of the lower dies;
coupling a plurality of vertical wires to the lower die stack, wherein each vertical wire extends from one of the lower dies;
stacking a spacer on the substrate;
stacking an upper die stack on the spacer, wherein the upper die stack includes a plurality of upper dies stacked in a cascading arrangement; and
coupling the plurality of vertical wires to the upper die stack, wherein each vertical wire extends from one of the lower dies to one of the upper dies.

18. The method of claim 17, further comprising:
stacking an input-and-output extender (IOE) on the substrate, wherein stacking the spacer on the substrate comprises stacking the spacer on the IOE; and
electrically coupling the IOE to the substrate and to one of the lower dies.

19. The method of claim 17, further comprising:
stacking a semiconductor structure on the substrate, wherein the semiconductor structure includes an Application-Specific Integrated Circuit (ASIC), a capacitor, or an inductor; and
electrically coupling the semiconductor structure to the substrate.

20. The method of claim 17, further comprising:
forming an encapsulant around the lower die stack and the upper die stack, wherein the encapsulant is formed such that a portion of an uppermost upper die of the upper die stack is not covered by the encapsulant.
